(19) United States
(12) Patent Application Publication
(10) Pub. No.: US 2026/0176739 A1
(43) Pub. Date: Jun. 25, 2026

(54) METHOD FOR DEPOSITING A LAYER OF ORGANIC/INORGANIC HYBRID OR INORGANIC MATERIALS ON A SUBSTRATE

(71) Applicants: TRIXELL, MOIRANS (FR); COMMISSARIAT A L'ENERGIE ATOMIQUE ET AUX ENERGIES ALTERNATIVES, PARIS (FR)

(72) Inventors: Louis GRENET, GRENOBLE (FR); Fabrice EMIEUX, GRENOBLE (FR); Jean-Marie VERILHAC, GRENOBLE (FR)

(21) Appl. No.: 19/125,716

(22) PCT Filed: Oct. 25, 2023
(86) PCT No.: PCT/EP2023/079830

§ 371 Date: Apr. 29, 2025

(30) Foreign Application Priority Data
Nov. 3, 2022 (FR) 2211437

(51) Int. Cl. C23C 14/24; C23C 14/06

(52) U.S. Cl. CPC C23C 14/24; C23C 14/0694

(57) ABSTRACT

A process for the deposition of a layer of an inorganic or organic/inorganic hybrid material on a substrate for the manufacture of an electronic, optoelectronic and/or optical device, includes: a step of preparation of a target; a step of positioning the target on a susceptor in a sublimation furnace, the target being positioned in the furnace facing the substrate to be covered; and a step of heating the target via the susceptor in order to deposit the layer of inorganic or organic/inorganic hybrid material on the substrate by sublimation; wherein, the target comprising a plurality of subtargets, the step of preparation of the target makes it possible to obtain subtargets having a variable thickness and/or the step of preparation of the target makes it possible to obtain subtargets which overlap.

### CROSS-REFERENCE TO RELATED APPLICATIONS

This application is a National Stage of International patent application PCT/EP 2023/079830, filed on Oct. 25, 2023, which claims priority to foreign French patent application No. FR 2211437, filed on Nov. 3, 2022, the disclosures of which are incorporated by reference in their entireties.

### FIELD OF THE INVENTION

The invention relates to the deposition by sublimation of layers of inorganic or organic/inorganic hybrid materials such as perovskites. In particular, the invention relates to deposition by sublimation using targets comprising several subtargets and making possible the deposition of uniform layers over a large surface area (typically over a surface area of greater than or equal to 25cm² ).

### BACKGROUND

The deposition of layers of inorganic or organic/inorganic hybrid materials is used in various applications, such as the manufacture of electronic, optical or optoelectronic devices based on inorganic or organic/inorganic hybrid materials (for example these may be LEDs, photodetectors, scintillators or also transistors). At present, it is possible to deposit a layer of inorganic or organic/inorganic hybrid materials, such as perovskites, using the close space sublimation (CSS) method. For this purpose, a target comprising inorganic or organic/inorganic hybrid materials is placed on a susceptor, facing a substrate on which the layer is to be deposited, in a close space sublimation furnace. The furnace also comprises a heating system as well as a pumping system making it possible to achieve a vacuum in the furnace. When the target is heated with the heating system, the materials of the target are sublimated and condense on the substrate. The deposition is directive, that is to say that the geometry of the target is re-encountered in that of the deposit (consequently, the surface of the deposit is identical to that of the target). This is because the sublimation is normal to the surface of the target and the mean free path of the entities in the vapor phase is greater than or comparable to the distance between the target and the substrate.

The targets are manufactured as compacted powder making it possible to obtain a solid target of uniform thickness, and thus making it possible to obtain a uniform layer deposited on the substrate. However, during deposition on large surface areas (for example greater than 25 cm²), it is difficult to obtain targets of the surface area of the deposit. In particular, since the pressure density for making a target has to be constant, the force exerted by the press has to be increased proportionally to the surface area. Thus, for large surface areas, presses exerting high pressures are necessary. Moreover, since the compacted powders are friable and the targets are of low thickness, an even greater pressure density may be necessary in order to obtain a solid target of large surface area having a uniform thickness.

Thus, it is possible to produce targets in the form of tiling, that is to say several subtargets each representing a portion of the target. The apparent surface area of the subtargets forming the size of the deposit is arranged as a continuous surface area (i.e., not having “holes”). In other words, the subtargets are targets of smaller surface areas which can subsequently be assembled on a susceptor. Targets of smaller surface areas can be manufactured more easily because they do not require high-pressure presses. For example, there exist targets comprising a tiling of subtargets having rectangular or square subtargets, as illustrated for example in FIG. 1, representing a target comprising four subtargets seen from above.

However, the sublimation takes place not only normally to the upper surface of the subtargets of the tiling but also by the edge faces of the subtargets. Consequently, the surface area of the subtargets decreases during the deposition, the subtargets become disconnected and the deposit with respect to the joints is thinner. Thus, a simple tiling, as represented in FIG. 1, does not make it possible to obtain uniform deposition.

### SUMMARY OF THE INVENTION

In order to respond to the problems encountered in the state of the art, a subject-matter of the invention is a process for the deposition by sublimation of a uniform layer of inorganic or organic/inorganic hybrid materials on a substrate of large surface area (typically on surface areas of greater than or equal to 25 cm²).

In particular, the invention improves the situation by providing a process for the deposition of a layer of an inorganic or organic/inorganic hybrid material on a substrate for the manufacture of an electronic, optoelectronic and/or optical device, said process comprising: a step of preparation of a target; a step of positioning the target on a susceptor in a sublimation furnace, said target being positioned in the furnace facing the substrate to be covered; and a step of heating the target via the susceptor in order to deposit the layer of inorganic material on the substrate by sublimation; characterized in that, the target comprising a plurality of subtargets, the step of preparation of the target makes it possible to obtain subtargets having a variable thickness and/or the step of preparation of the target makes it possible to obtain subtargets which overlap.

As indicated above, the sublimation takes place not only by the center of the subtargets but also by the edge faces of the subtargets of the tiling. The invention is particularly advantageous because it makes it possible to compensate for the sublimation by the edge faces by providing a nonuniform thickness and/or with an overlapping between the several subtargets. Thus, it is possible to manufacture subtargets making possible the sublimation of materials onto substrates of large surface areas while obtaining a uniform sublimated layer. Moreover, the invention is particularly advantageous because it does not require the use of a high-pressure press and thus simplifies the manufacture of the targets.

In one embodiment, each subtarget having a central region and a peripheral region, the thickness of said subtarget is greater in said peripheral region.

In one embodiment, at least two subtargets of the target fit together.

In one embodiment, the two subtargets are beveled.

In one embodiment, the two subtargets are of square-wave shape.

In one embodiment, the subtargets overlap to form several strata.

In one embodiment, each stratum has one and the same thickness.

In one embodiment, each stratum has a different thickness.

In one embodiment, at least two strata are made of different materials.

In one embodiment, the subtargets overlap in a disorganized manner.

The invention also improves the situation by providing a target for carrying out a deposition by sublimation of a layer of one or more inorganic or organic/inorganic hybrid materials on a substrate, the target being formed of several subtargets, the subtargets having a variable thickness and/or overlapping.

### BRIEF DESCRIPTION OF THE DRAWINGS

A better understanding of the invention will be obtained and other advantages will become apparent on reading the description which will follow, given without limitation, and by virtue of the figures, among which:

FIG. 1 illustrates an example of the state of the art of a target with simple tiling;

FIG. 2 represents an example of a process for the deposition by sublimation of a layer of one or more inorganic or organic/inorganic hybrid materials on a substrate;

FIG. 3 represents an example of a system for depositing a layer of one or more inorganic or organic/inorganic hybrid materials on a substrate by sublimation;

FIG. 4a represents an example of a target comprising a tiling of subtargets, seen in cross-section;

FIG. 4b represents an example of a target comprising a tiling of subtargets, seen in cross-section;

FIG. 5 represents an example of a target comprising a tiling of subtargets, seen in cross-section;

FIG. 6a represents an example of a target comprising a tiling of subtargets, seen in cross-section;

FIG. 6b represents an example of a target comprising a tiling of subtargets, seen in cross-section; and

FIG. 6c represents an example of a target comprising a tiling of subtargets, seen in cross-section;

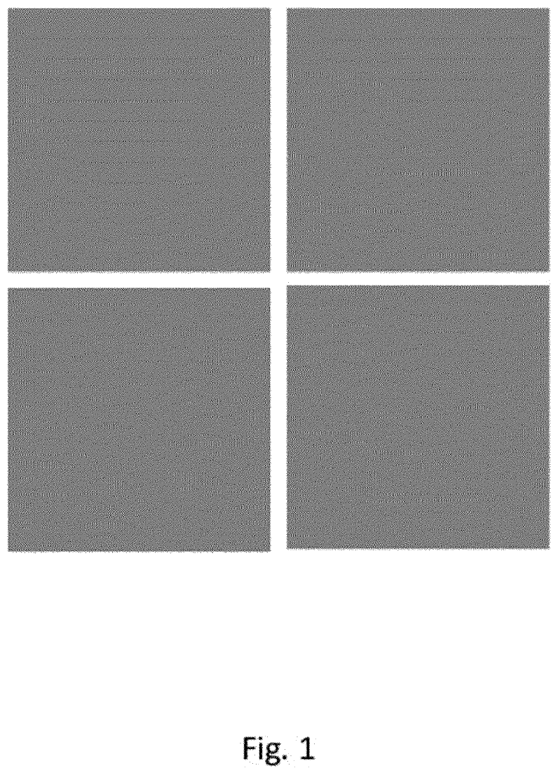

### DETAILED DESCRIPTION

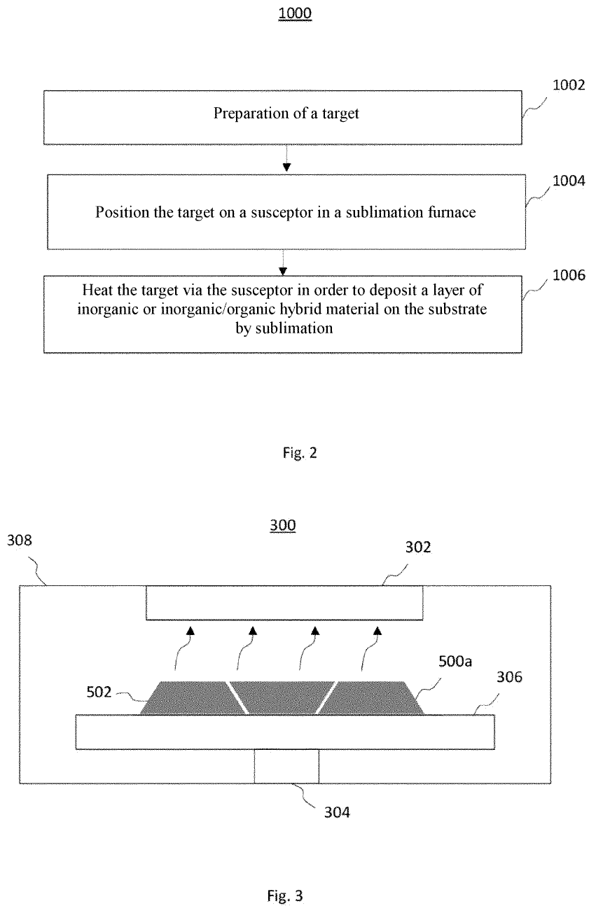

FIG. 2 illustrates a process for the deposition 100 of a layer of an inorganic or organic/inorganic hybrid material on a substrate 302 for the manufacture of an electronic, optoelectronic and/or optical device.

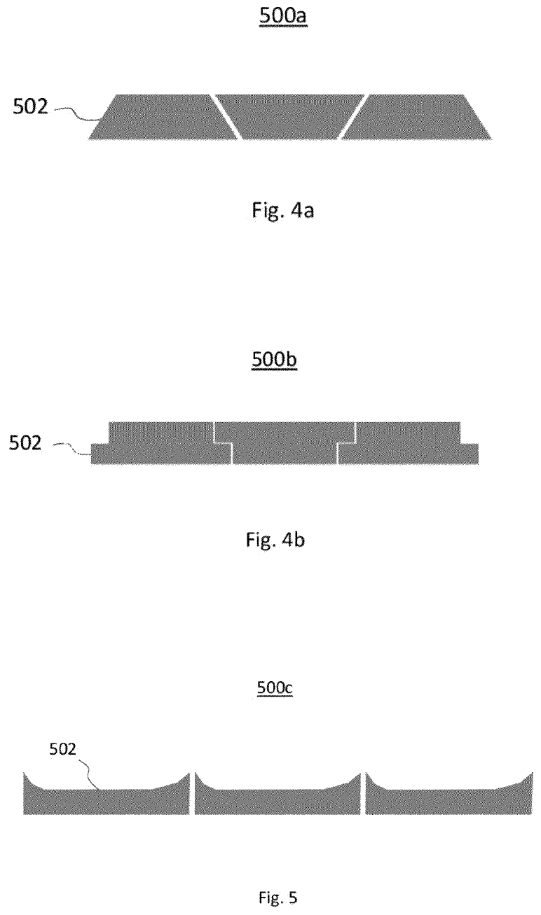

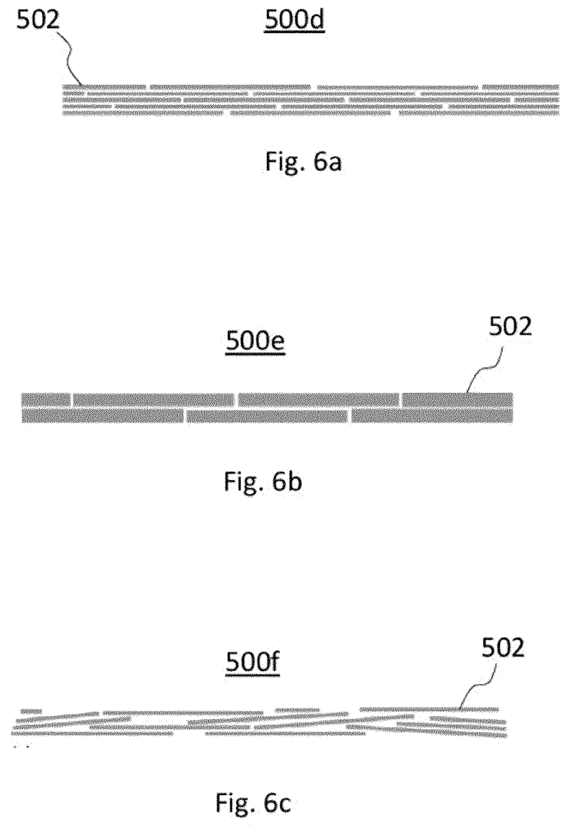

In the block 1002, the process 1000 comprises a step of preparation of a target 500a, 500b, 500c, 500d, 500e, 500f. As illustrated in FIGS. 4a to 6c representing examples of targets, the target 500a, 500b, 500c, 500d, 500e, 500f comprises a plurality of subtargets 502. The step of preparation of the target 500a, 500b, 500c, 500d, 500e, 500f makes it possible to obtain subtargets 502 having a variable thickness and/or the step of preparation of the target 500a, 500b, 500c, 500d, 500e, 500f makes it possible to obtain subtargets which overlap. In particular, FIGS. 4a, 4b, 6a, 6b and 6c represent targets 500a, 500b, 500d, 500e, 500f having subtargets 502 which overlap and FIG. 5 represents a target 500c having subtargets having a variable thickness. The thickness of the subtargets represents one dimension. In particular, the thickness of the subtargets represents a distance between the lower face (being the face in contact with a susceptor 306) and the upper face of the subtarget, which is opposite the lower face.

For example, when the subtargets overlap, the subtargets 502 form a target for which, over a fraction (from 1% to 25%) of a total surface area of the target, several subtargets are superimposed in the thickness of the target. The overlapping can be established over a few millimeters (from 0.5 to 10 mm and preferentially 2 mm). In another example, when the subtargets overlap, the target comprises subtargets 502 for which, over the whole of the surface area of the target, several subtargets 502 are superimposed in the thickness of the target. This superimposition can be obtained by any number of subtargets greater than two (and preferentially less than five). The overlapping can be ordered (ordered arrangement of the subtargets, characterized in particular in that, at each point of the tiling, the number of subtargets superimposed in the thickness is identical) or disordered.

The subtargets comprise a peripheral region and a central region. The peripheral region represents the entire perimeter of a subtarget. In FIGS. 4a, 4b and 4c and 5, the thickness of the central region and the thickness of the peripheral region are different. For example, as illustrated in FIGS. 4a and 4b, at least two subtargets 502 of the target 500a fit together. In particular, in FIG. 4a, the subtargets 502 are beveled. In the example of FIG. 4b, the subtargets 502 are of square-wave shape. In particular, in these two examples, the targets 500a, 500b comprise at least three subtargets, a first subtarget, a second subtarget and a third subtarget. The three subtargets are placed side by side. Each of the subtargets has one and same volume and has one and the same beveling angle, with an upper side and a lower side, one of the sides being greater than the other. For the first and third subtargets, the lower side is greater than the upper side and, for the second subtargets, the upper side is greater than the lower side.

In another example, the target 500a can comprise beveled subtargets 502 and subtargets 502 of square-wave shape.

In another example, as illustrated in FIG. 5, each subtarget 502 has a central region and a peripheral region, and the thickness of the subtarget 502 is greater in the peripheral region. The thickness can vary gradually, as represented in FIG. 5, or abruptly (that is to say, for example, with a rim placed on the subtarget 502). It is noted that FIG. 5 is in cross-section; thus, the variation in thickness is represented only on two of the ends of the subtargets 502.

In another example, as illustrated in FIGS. 6a to 6c, the subtargets overlap to form several strata. A subtarget comprises two endings. When the subtargets form strata, the endings of one subtarget are not coherent with the endings of a subtarget in the stratum on top or below. For example, in the example of FIGS. 6a and 6b, each stratum has one and the same thickness. In the example of FIG. 6c, each stratum has a different thickness. In addition, in the example of FIG. 6c, the subtargets 502 overlap in a disorganized manner. In another example, the strata can have a different thickness while overlapping each other in an organized manner.

It is noted that the targets 500a, 500b, 500c, 500d, 500e, 500f of FIGS. 4a-6c are represented in cross-section. Seen from above, the subtargets 502 can be rectangular, square or parallelepipedal. In other examples, the subtargets can be circular, triangular or also of any other shape suitable for the application for which the target 500a, 500b, 500c, 500d, 500e, 500f is used. In addition, the number of subtargets 502 is adapted to the dimensions of the substrate 302 onto which the layer of inorganic or organic/inorganic hybrid materials is sublimated. For example, in the example of FIG. 4a, the target 500a comprises three subtargets 502 seen in cross-section. The target 500a can comprise two or more subtargets 502. In addition, seen from above, the target 500a can form a square, a rectangle, or any other shape suitable for the application for which the target 500a, 500b, 500c, 500d, 500e, 500f is used.

The targets 500a, 500b, 500c, 500d, 500e, 500f are formed using powders of pressed inorganic or organic/inorganic hybrid materials. Each subtarget 502 is manufactured individually and then the subtargets are assembled in order to form the target 500a, 500b, 500c, 500d, 500e, 500f. A target can be made of one material. Thus, each subtarget of one and the same target can be made of one and the same material or of one and the same mixture of materials.

The targets 500a, 500b, 500c, 500d, 500e, 500f are made of inorganic or organic/inorganic hybrid materials which can be, for example, perovskites, such as perovskites of general chemical formula ABX₃, including mixed compositions, such as A⁽¹⁾ _{1-(y2+. . . +yn)} A⁽²⁾ _{y2 . . .} A⁽ⁿ⁾ _{yn} B⁽¹⁾ _{1-(z2+. . . +zm) B}⁽²⁾_{z2 . . . B}^{(m)} _{zm} X⁽¹⁾ _{3-(x2+. . . +xp)} X⁽²⁾ ₓ₂. . . X^{(p)} ₓₚ with A⁽ⁿ⁾ and B⁽ⁿ⁾ cations and X⁽ⁿ⁾ anions, the compositions observing electronic neutrality, with y2 and yn the respective proportions of the cations A⁽²⁾ and A⁽ⁿ⁾, z₂ and Zₘ the respective proportions of the cations B⁽²⁾ and B^{(m)}, and x₂ and xₚ the respective proportions of the anions X⁽²⁾ and X₍ₚ₎.

For example, A is chosen from Cs, Rb, K, Li, and Na (inorganic perovskite) or CH₃NH₃, CH₅N₂ (hybrid perovskite); B is chosen from Pb, Sn, Ge, Hg and Cd; X is chosen from CI, Br, I and F. For example, it is CsPbBr₃.

In another example, it is also possible to have alloys of 2 to 5 elements on one of the sites, on two of the sites or on the three sites A, B and X. For example, it is possible to choose a material with X=ClₖBr_{I}I_{1-k-I} with 0≤k, I≤1 and 0≤k+I≤1. It is the same for the sites A and B.

In another example, it is also possible to have double cells with A=A'₂, B=C'¹+D'³+ and X₃=X′₆, i.e. a material of formula A′₂C¹+D³+X₆ with: A′ chosen from Cs, Rb, K, Li and Na; X′ chosen from Cl, Br, I and F; C^{′}1+ chosen from Ag, Au, TI, Li, Na, K and Rb, and D³+ chosen from Al, Ga, In, Sb and Bi.

Preferably, according to this alternative form, the perovskite material has the formula Cs₂AgBiBr₆.

The invention also applies to all other compositions similar to perovskites: materials with the composition A₂B⁴⁺X₆, such as, for example, CS₂Te⁴+I₆, materials with the composition A₃B₂³⁺X₉, such as, for example, CS₃Bi₂I₉, or other types of materials (chalcogenides, rudorfites, and the like).

In the case where the target 500a, 500b, 500c, 500d, 500e, 500f is of formula ABX₃, the target 500a, 500b, 500c, 500d, 500e, 500f can be formed of a mixture of elementary particles A, B and X.

In other examples, the target 500a, 500b, 500c, 500d, 500e, 500f of formula ABX₃ can be formed:
of a mixture of AX and BX₂ binary particles,
of a mixture of AX, BX₂ and ABX₃ particles,
of ABX₃ particles, which makes it possible to have directly the right composition and the right phase of the material to be sublimated; these particles can, for example, be small single crystals formed by the liquid route, by the Bridgman route or other solution.

It is also possible to use mixtures comprising more than two types of binary particles. For example, the compound Cs₂AgBiBr₆ can be obtained from CsBr, AgBr and BiBr₃ precursors.

In the case where the target 20 is of formula A′₂C¹⁺D³⁺X₆, the target can be composed:
of a mixture of A′X, C¹⁺X and D³⁺X₃ binary particles,
of a mixture of A′X, C¹⁺X and D³⁺X₃ and A′₂C¹⁺D³⁺X₆ particles,
of A′₂C¹⁺D³⁺X₆ particles, which makes it possible to have directly the right composition and the right phase of the material to be sublimated.

Compositions which are more complex and/or which involve a greater number of precursors can also be envisaged. Other inorganic or organic/inorganic hybrid materials can also be used, such as Cd_{1-x-y}HgₓZn_{y}Te_{1-z-t}Se_{z}St (with 0≤x, y, z, t≤1), Sb₂(S₁₋ₓSeₓ)₃ (with 0≤x≤1), or any other material capable of being deposited by close space sublimation.

Each target 500a, 500b, 500c, 500d, 500e, 500f of the examples described above measures at least 5 cm in width, that is to say that at least one of the sides of the target measures at least 5 cm. In one example, the targets 500a, 500b, 500c, 500d, 500e, 500f measure at least 10 cm in width. In another example, the targets 500a, 500b, 500c, 500d, 500e, 500f measure at least 20 cm in width.

In one example, the target 500a, 500b, 500c, 500d, 500e, 500f comprises subtargets of different materials. For example, the target 500a, 500b, 500c, 500d, 500e, 500f comprises at least two strata made of different materials. For example, in the example of FIG. 6b, the target 500e comprises two strata: an upper stratum and a lower stratum. The upper stratum can be made of a first material and the lower stratum can be made of a second material. In another example, FIG. 5 illustrates the target 500c comprising three subtargets 502: a first subtarget, a second subtarget and a third subtarget. The first subtarget can be made of a first material, the second subtarget can be made of a second material and the third subtarget can be made of a third material.

In the block 1004, the process 1000 comprises a step of positioning the target 500a, 500b, 500c, 500d, 500e, 500f on a susceptor 306 in a sublimation furnace 308, the target 500a, 500b, 500c, 500d, 500e, 500f being positioned in the furnace 308 facing the substrate 302 to be covered. The target 500a, 500b, 500c, 500d, 500e, 500f can be, for example, manufactured on the susceptor 306 which is subsequently placed in the furnace 308. In another example, the target 500a, 500b, 500c, 500d, 500e, 500f is manufactured on a support and transferred onto the susceptor 306. The furnace can be a close space sublimation furnace. The susceptor 306 is made of conductive materials. The furnace 308 comprises a gas outlet, connected to a pumping system making it possible to achieve a vacuum Pfurnace ranging, for example, from 0.00001 Pa to 1 Pa. The Pfurnace value depends on the furnace 308 used.

In the block 1006, the process 1000 comprises a step of heating the target 500a, 500b, 500c, 500d, 500e, 500f via the susceptor 306 in order to deposit the layer of inorganic material on the substrate 302 by sublimation. For example, as illustrated in FIG. 3 representing a system 300 for depositing a layer of inorganic or organic/inorganic hybrid materials on the substrate 302 by sublimation, the susceptor 306 can be placed on a heating element 304. For example, the heating element 304 can be a lamp, a resistor, or any other heating system. The deposition by sublimation is carried out by heating the susceptor 306 with the heating element 304 with, for example, a temperature of 400° C. (±100° C.) and a substrate temperature of 300° C. (+150° C.). In order to ensure the deposition of the layer, the temperature of the substrate is lower by 100° C. (from 300° C. to 20° C. lower) than the temperature of the target 500a, 500b, 500c, 500d, 500e, 500f. Temperature rise gradients in order to reach the sublimation temperatures can be, for example, 1°C/s. The temperature can be adjusted depending on the materials and thicknesses of the targets.

The invention described above thus makes it possible to obtain uniform layers of inorganic or organic/inorganic hybrid materials, even for large-sized substrates. This is because the subtargets make it possible to easily manufacture solid targets. In addition, the subtargets which overlap and/or which have a variable thickness make it possible to compensate for the fact that the sublimation takes place more rapidly by the edge faces of the subtargets of the tiling than by the center of the subtargets.

Although the invention has been illustrated and described in detail with the help of a preferred embodiment, the invention is not limited to the examples disclosed. Other alternative forms can be deduced by a person skilled in the art without departing from the scope of protection of the claimed invention. For example, the number of subtargets per target can vary according to the applications. Furthermore, the shapes, thicknesses and number of layers of the subtargets can vary according to the applications. The shapes can also be combined.

1. A process for the deposition of a layer of an inorganic or organic/inorganic hybrid material on a substrate for the manufacture of an active layer in an electronic, optoelectronic and/or optical device, said process comprising:
a step of preparation of a target;
a step of positioning the target on a susceptor in a sublimation furnace, said target being positioned in the furnace facing the substrate to be covered; and
a step of heating the target via the susceptor in order to deposit the layer of inorganic or organic/inorganic hybrid material on the substrate by sublimation;
wherein, the target comprising a plurality of subtargets, each subtarget having a central region and a peripheral region, the step of preparation of the target makes it possible to obtain subtargets having a variable thickness, the thickness of the central region and the thickness of the peripheral region being different, and/or the step of preparation of the target makes it possible to obtain subtargets which overlap.

2. The deposition process as claimed in claim 1, each subtarget having a central region and a peripheral region, the thickness of said subtarget is greater in said peripheral region.

3. The deposition process as claimed in claim 1, wherein at least two subtargets of the target fit together.

4. The deposition process as claimed in claim 3, wherein the two subtargets are beveled.

5. The deposition process as claimed in claim 3, wherein the two subtargets are of square-wave shape.

6. The deposition process as claimed in claim 1, wherein the subtargets overlap to form several strata.

7. The deposition process as claimed in claim 6, wherein each stratum has one and the same thickness.

8. The deposition process as claimed in claim 6, wherein each stratum has a different thickness.

9. The deposition process as claimed in claim 6, wherein at least two strata are made of different materials.

10. The deposition process as claimed in claim 1, wherein the subtargets overlap in a disorganized manner.

11. A target for carrying out a deposition by sublimation of a layer of one or more inorganic or organic/inorganic hybrid materials on a substrate, the target being formed of several subtargets, each subtarget having a central region and a peripheral region, the subtargets having a variable thickness, the thickness of the central region and the thickness of the peripheral region being different and/or the subtargets overlapping.
